(19) United States
(12) Patent Application Publication
(10) Pub. No.: US 2009/0314350 A1
(43) Pub. Date: Dec. 24, 2009

(54) ORGANIC SOLAR CELLS AND METHOD OF MANUFACTURING THE SAME

(75) Inventors: Hee Tae Jung, Daejeon (KR); Jae Hyun Lee, Seoul (KR); Dae Woo Kim, Jeollabuk-do (KR); Hong Jang, Gwangju (KR)

Correspondence Address: LAHIVE & COCKFIELD, LLP;FLOOR 30, SUITE 3000, ONE POST OFFICE SQUARE, BOSTON, MA, 02109, US

(73) Assignee: Korea Advanced Institute of Science and Technology, Daejeon (KR)

(21) Appl. No.: 12/477,375

(22) Filed: Jun. 3, 2009

(30) Foreign Application Priority Data
Jun. 18, 2008 (KR) 10-2008-0057357

(51) Int. Cl. H01L 51/44; H01L 51/48; H01L 51/46

(52) U.S. Cl. 136/263; 438/82; 257/E51.029; 257/E21.158

(57) ABSTRACT

An organic solar cell and a method of manufacturing the same. This invention relates to a method of manufacturing an organic solar cell including forming nano patterns on a photoactive layer using a nanoimprinting process, and applying a cathode electrode material on the photoactive layer having the nano patterns so that the cathode electrode material infiltrates the nano patterns of the photoactive layer, thus increasing electron conductivity and efficiently forming a pathway for the transfer of electrons, and to an organic solar cell manufactured through the method. This method reduces loss of photocurrent occurring as a result of aggregation of an electron acceptor material and improves molecular orientation of an electron donor in the nanoimprinting process to thus increase cell efficiency. Thereby, the organic solar cell having high efficiency is manufactured at low cost through a simple manufacturing process. The method can be applied to the fabrication of organic solar cells which use an environmentally friendly and recyclable energy source.

### CROSS-REFERENCES TO RELATED APPLICATION

This patent application claims the benefit of priority under 35 U.S.C. §119 of Korean Patent Application No. 10-2008-0057357 filed on Jun. 18, 2008, the contents of which are incorporated herein by reference.

### BACKGROUND OF THE INVENTION

1. Field of the Invention

The present invention relates to an organic solar cell and a method of manufacturing the same. More particularly, the present invention relates to a method of manufacturing an organic solar cell, including forming nano patterns on a photoactive layer of the organic solar cell using a nanoimprinting process, and applying a cathode electrode material on the photoactive layer having the nano patterns so that the cathode electrode material infiltrates the nano patterns of the photoactive layer, thus increasing electron conductivity and efficiently forming a pathway for the transfer of electrons, and to an organic solar cell manufactured through the above method.

2. Description of the Related Art

A solar cell is a semiconductor device for directly converting solar light energy into electrical energy, and is largely classified into, depending on the type of material used, a silicon solar cell and an organic solar cell. Whereas the silicon solar cell is difficult to use in the application of solar energy because silicon used therein is expensive and the reserve thereof is limited, the organic solar cell is recently receiving attention thanks to advantages such as low manufacturing cost, the easy manufacturing process which does not need a special vacuum system, and a probability of manufacturing a flexible device through a low-temperature process. In particular, in the case of an organic solar cell which may be manufactured through a solution process such as spin coating, dip coating or doctor blade coating, without a need for vacuum deposition, it is very advantageous in terms of the manufacturing cost or ease of the processing.

In order to improve solar cell efficiency, thorough research into the materials and structures of the organic solar cell has been conducted to date. In particular, a bulk-heterojunction structure using a mixture of an electron donor and an electron acceptor is known to exhibit the highest efficiency.

However, the bulk-heterojunction structure is problematic because excitons which are electron-hole pairs formed in the electron donor such as a conductive polymer by solar light have a diffusion distance of only about 10 nm in the polymer, and thus they are recombined and disappear when not reaching the interface between the electron donor and the electron acceptor within the above distance. Further, such an electron donor/acceptor structure is not externally artificially determined, but is set by the type of solvent, composition of the mixture, spin coating conditions, drying conditions, thermal treatment conditions, and the other post treatment conditions and mainly depends on self-assembling properties of the conductive polymer, thus making it difficult to manufacture an ideal electron donor/acceptor structure.

Further, after separation of the excitons into electrons and holes at the interface between the electron donor and the electron acceptor, the electrons and the holes are respectively transferred to a metal electrode acting as a cathode and a transparent electrode acting as an anode. To this end, the electron donor/acceptor structure should be co-continuous, with the entire electron donor provided in a continuous form and disposed to be in contact with the anode and the entire electron acceptor provided in a continuous form and disposed to be in contact with the cathode. However, the electron donor/acceptor structure cannot be artificially determined but is dependent on phase separation properties after the mixing of materials, thus making it impossible to obtain such an ideal structure.

Actually, the bulk-heterojunction structure, obtained by applying the mixture of electron donor and electron acceptor dissolved in a solvent through spin coating, is not of a co-continuous form in which the electron donor and the electron acceptor are respectively provided in a continuous form. Further, either the electron donor or the electron acceptor become clustered and thus become provided in the form of islands depending on the relative amount thereof. Also, in the case where the electron donor and the electron acceptor are mixed in similar amounts, an electron donor-rich region constitutes islands which are not connected but are isolated, negatively affecting electron conductivity. To solve this problem, a bilayer structure may be adopted. In this case, however, the interfacial area between the electron donor and the electron acceptor is small, undesirably decreasing the efficiency.

FIG. 1 shows an ideal electron donor/acceptor structure of a photoactive layer, in which the electron donor is provided in a continuous form and is disposed to be in contact with a transparent electrode acting as a anode, and in which the interfacial area between the electron donor and the electron acceptor is very large and the interface between the electron donor and the electron acceptor is located at a distance less than 10 nm from any position of the electron donor. As shown in FIG. 1, the bulk-heterojunction structure is configured such that both the electron donor and the electron acceptor are aligned in a direction perpendicular to the electrodes to minimize the transfer distance of electrons and holes generated by photoactivity, and also such that the electron acceptor is provided in a continuous form and is disposed to be in contact with a metal electrode acting as a cathode.

As illustrated in FIG. 2, however, in an actual bulk-heterojunction structure, the electron donor and the electron acceptor are phase-separated in the form of a sea-island structure, and the size of the electron acceptor-rich island structure varies depending on the process conditions including the composition ratio, the type of solvent, and drying conditions.

Thus, in order to artificially control the electron donor/acceptor structure, there has been proposed a method of applying an electron donor, subjecting the electron donor to nanoimprinting thus forming the electron donor having a predetermined nano pattern structure, and depositing an electron acceptor on the electron donor (D. M. N. M. Dissanayake et al., Applied Physics Letters, 90:253502, 2007). This method cannot form nano patterns shorter than the diffusion distance of excitons in the polymer, and thus, a low molecular organic material in which the diffusion distance of excitons is relatively long is used as the electron acceptor, in lieu of the electron donor using the polymer. However, the deposition of the electron acceptor undesirably requires an expensive vacuum system and a long process time, and incurs problems such as the efficiency of the resultant solar cell being very low.

Also, to overcome these problems, there has been proposed a method of applying an electron donor which is a conductive polymer and then applying heat upon nanoimprinting so that the applied electron donor polymer is made insoluble to thus prevent the dissolution of the applied electron donor upon subsequent application of an electron acceptor (M. S. Kim et al., Applied Physics Letters, 90:123113, 2007). According to this method, because the period of the nanoimprint is about 500˜700 nm much greater than the diffusion distance of the excitons, the efficiency of the resultant solar cell is slightly improved compared to when using the bilayer structure but is rather decreased compared to when using the bulk-heterojunction structure. Moreover, because the electron donor is made insoluble, hole conductivity is undesirably lowered.

Therefore, in order to artificially control the structure of the electron acceptor with the use of the bulk-heterojunction structure having the highest efficiency to date, there has been proposed a method using a microcontact printing process for transferring a specific organic material using a mold similar to the nanoimprint (F. C. Chen et al., Applied Physics Letters, 93:023307, 2008). This method includes forming a self-assembled monolayer, applying a mixed solution of an electron donor and an electron acceptor on the self-assembled monolayer, and drying it to induce predetermined phase separation through interaction with the self-assembled monolayer, thereby achieving shape-controlled phase separation different from general phase separation. However, this method enables the formation of only patterns having a size larger than when using the nanoimprinting process. When the size of the patterns is decreased, it is difficult to induce the phase separation adapted for the self-assembled monolayer. Further, resistance is increased due to the self-assembled monolayer formed under the photoactive layer, and thus there is a limitation in increasing the efficiency.

Also, a method of applying a photoactive organic material using a brush to thereby induce a molecular array and improve efficiency is disclosed (Korean Unexamined Patent Publication No. 10-2008-0021413). This method is advantageous because a continuous process may be carried out in a roll-to-roll manner, but the degree of molecular orientation is limited, thus making it difficult to greatly increase efficiency.

### SUMMARY OF THE INVENTION

Leading to the present invention, thorough research carried out by the present inventors aiming to solve the problems encountered in the related art resulted in the finding that, when an organic solar cell is manufactured by forming nano patterns on a photoactive layer using a nanoimprinting process and then applying a cathode electrode material on the photoactive layer having the nano patterns so that a cathode electrode infiltrates the nano patterns of the photoactive layer, electrical connection of an electron acceptor material of the photoactive layer and orientation of an electron donor material thereof may be improved, thus increasing electron conductivity and hole conductivity, consequently obtaining power conversion efficiency much greater than that of a conventional organic solar cell using a bulk-heterojunction photoactive layer.

Accordingly, the present invention provides an organic solar cell having high power conversion efficiency using a nanoimprinting process, and a method of manufacturing the organic solar cell.

An aspect of the present invention is to provide a method of manufacturing an organic solar cell, including (a) applying a transparent electrode material on a substrate, thus forming a transparent electrode, (b) applying a mixture of an electron donor material and an electron acceptor material dissolved in a solvent on the transparent electrode, thus forming a photoactive layer, and then forming patterns on the photoactive layer using a nanoimprinting process, and (c) applying a cathode electrode material on the patterned photoactive layer, thus forming a cathode electrode, and also to provide an organic solar cell, manufactured using the above method and including a photoactive layer having a bulk-heterojunction structure of an electron donor and an electron acceptor, in which a cathode electrode material infiltrates the photoactive layer.

Another aspect of the present invention is to provide a method of manufacturing an organic solar cell, including (a) applying indium tin oxide on a glass substrate, thus forming a transparent electrode, (b) applying poly(3,4-ethylenedioxythiophene)-polystyrenesulfonate on the transparent electrode, thus forming a hole transfer layer, (c) applying a mixture of poly-3-hexylthiophene and (6,6)-phenyl-C₆₁-butyric acid methyl ester dissolved in dichlorobenzene on the hole transfer layer, thus forming a photoactive layer, and then forming patterns on the photoactive layer using a nanoimprinting process, (d) applying lithium fluoride on the patterned photoactive layer, thus forming an electron transfer layer and (e) applying aluminum on the electron transfer layer, thus forming a cathode electrode, and also to provide an organic solar cell, manufactured using the above method and including a photoactive layer having a bulk-heterojunction structure of poly-3-hexylthiophene and (6,6)-phenyl-C₆₁-butyric acid methyl ester, in which a cathode electrode material infiltrates the photoactive layer.

### BRIEF DESCRIPTION OF THE DRAWINGS

FIG. 1 schematically shows an ideal structure of a photoactive layer of an organic solar cell;

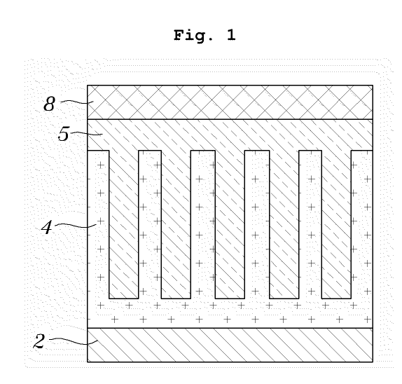

FIG. 2 schematically shows a photoactive layer having a bulk-heterojunction structure of a conventional organic solar cell;

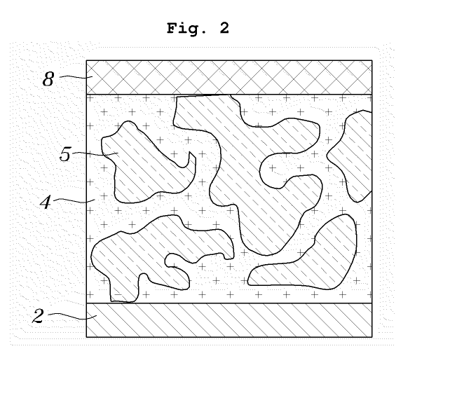

FIG. 3 schematically shows the conventional solar cell including the photoactive layer having a bulk-heterojunction structure;

FIG. 4 schematically shows an organic solar cell according to the present invention;

FIG. 5 schematically shows a process of manufacturing the organic solar cell according to the present invention;

FIG. 6 shows a scanning electron microscope (SEM) image of a mold used in Examples 1 and 2 according to the present invention; and

FIG. 7 shows a current-voltage curve of the organic solar cell according to the present invention.

### DETAILED DESCRIPTION OF THE INVENTION

Hereinafter, a detailed description will be given of the present invention.

According to an embodiment of the present invention, a method of manufacturing an organic solar cell includes (a) applying a transparent electrode material on a substrate, thus forming a transparent electrode, (b) applying, on the transparent electrode thus formed, a mixture of an electron donor material and an electron acceptor material dissolved in a solvent, thus forming a photoactive layer, and then forming patterns on the photoactive layer using a nanoimprinting process, and (c) applying a cathode electrode material on the patterned photoactive layer, thus forming a cathode electrode.

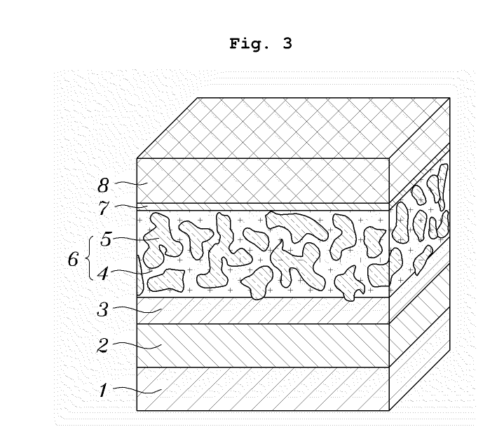

A conventional organic solar cell including a photoactive layer having a bulk-heterojunction structure includes, as shown in FIG. 3, a transparent substrate 1, a transparent electrode layer 2, a hole transfer layer 3, a photoactive layer 6 composed of a mixture of an electron donor 4 and an electron acceptor 5, an electron transfer layer 7 and a cathode electrode layer 8. The photoactive layer 6 of the conventional organic solar cell is formed by mixing the electron donor material and the electron acceptor material using a solvent able to simultaneously dissolve these materials, applying the mixture on the hole transfer layer 3, and evaporating the solvent from the mixture applied on the hole transfer layer 3, so that phase separation occurs spontaneously and randomly to thus form a bulk-heterojunction structure. In the bulk-heterojunction structure thus formed, because phase separation occurs randomly while evaporating the solvent of the mixture applied on the hole transfer layer, electron donor and acceptor phases cannot have a co-continuous structure, and part of the phases is isolated, thus blocking a pathway for the transfer of electrons or holes to the electrodes.

Also, when the bulk-heterojunction structure of the photoactive layer is formed, if the amount of the electron donor material is relatively larger than that of the electron acceptor material, it is easy to form a sea-island structure in which the electron donor forms the sea and the electron acceptor forms islands. In contrast, if the amount of the electron donor material is relatively smaller than that of the electron acceptor material, it is easy to form a sea-island structure in which the electron donor forms islands and the electron acceptor forms the sea. Even when the currently available poly(3-hexylthiophene) is used as the electron donor and the currently available (6,6)-phenyl-C₆₁-butyric acid methyl ester (PCBM) is used as the electron acceptor, PCBM mainly forms islands. Although electrons should be transferred to the cathode electrode through PCBM, a pathway for the transfer of electrons may be blocked, undesirably decreasing the efficiency.

Also, in the conventional organic solar cell having a bulk-heterojunction structure, because the structure of the electron donor phase is randomly formed, the direction of molecular alignment of the electron donor is also randomly set. In the electron donor, transfer of holes varies depending on the direction of molecular alignment of the electron donor. Accordingly, the random molecular alignment of the conventional organic solar cell having a bulk-heterojunction structure is not favorable in terms of efficient hole transfer. Moreover, transfer of electrons in the electron acceptor also varies depending on the structure of the electron acceptor. In the case where a low molecular material such as PCBM is used, the intermolecular distance should be very short to promote electron transfer. As the electron transfer is carried out by means of a hopping mechanism, the electron transfer rate becomes very slow.

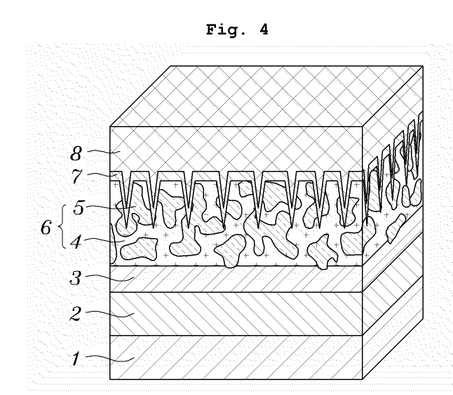

Therefore, as shown in FIG. 4, the present invention is directed to the organic solar cell which is configured such that nano patterns are formed on a photoactive layer having a bulk-heterojunction structure using a nanoimprinting process, and an electron transfer layer and a cathode electrode layer are formed on the photoactive layer having the nano patterns, whereby the cathode electrode layer infiltrates the nano patterns of the photoactive layer.

The organic solar cell thus configured continues the broken pathway for the transfer of electrons, thereby facilitating the transfer of electrons and also reducing the number of electrons that disappear, consequently increasing the total photocurrent. Further, in the present invention, as electrons are transferred to the cathode electrode layer made of a highly conductive metal, without the use of a hopping mechanism, there are effects of increasing the electron transfer rate and reducing the electron transfer resistance. As well, when the nano patterns are formed on the surface of the photoactive layer using a nanoimprinting process, there is an effect of aligning electron donor molecules in a perpendicular direction, thus facilitating the transfer of holes to the transparent electrode, resulting in lowered electron transfer resistance and increased efficiency.

Also, in the organic solar cell according to the present invention, as the surface of the cathode electrode for reflecting light is not flat and is formed with uneven nano patterns, a phenomenon where part of incident light is not absorbed by the electron donor but travels and is reflected from the surface of the cathode electrode can be reduced, and also, reflection can occur in diverse directions from the surface of the cathode electrode, thus more efficiently using light.

According to the present invention, the method of manufacturing the organic solar cell includes applying the transparent electrode material on the substrate 1, thus forming the transparent electrode 2, applying, on the transparent electrode thus formed, the mixture of electron donor material and electron acceptor material dissolved in a solvent, thus forming the photoactive layer 6, forming the patterns on the photoactive layer 6 using a nanoimprinting process, and applying the cathode electrode material on the patterned photoactive layer 6, thus forming the cathode electrode 8.

In the present invention, examples of the substrate 1 include a glass substrate and a flexible polymer substrate, which are typically used in the art. The flexible polymer substrate has high chemical stability and mechanical strength and is transparent, and may be selected from the group consisting of polyethyleneterephthalate (PET), polyethylenenaphthalate (PEN), polyimide, polyetheretherketone (PEEK), polyethersulfone (PES) and polyetherimide (PEI).

In the present invention, the transparent electrode 2 is formed by applying the transparent electrode material on the substrate 1, and includes an organic transparent electrode using transparent oxide such as indium tin oxide (ITO), a conductive polymer, a graphene thin film, a graphene oxide thin film and a carbon nanotube thin film, and an organic-inorganic transparent electrode using a metal-combined carbon nanotube thin film.

In the present invention, the photoactive layer 6 is formed by applying the mixture of electron donor material and electron acceptor material dissolved in the solvent on the hole transfer layer 3. The electron donor material is an organic semiconductor such as an electrical conductive polymer or a low molecular organic semiconductor material, including a conductive polymer such as polythiophene, polyphenylenevinylene, polyfluorene, polypyrrole and copolymers of two or more thereof, and a low molecular organic semiconductor material such as pentacene, anthracene, tetracene, perylene, oligothiophene and derivatives thereof. Preferably, the electron donor material is selected from the group consisting of poly-3-hexylthiophene (P3HT), poly-3-octylthiophene (P30T), poly-p-phenylenevinylene (PPV), poly(9,9′-dioctylfluorene), poly(2-methoxy-5-(2-ethyl-hexyloxy)-1,4-phenylenevinylene (MEH-PPV), poly(2-methyl-5-(3′,7′-dimethyloctyloxy))-1,4-phenylenevinylene (MDMO-PPV) and mixtures thereof.

The electron acceptor material includes fullerene or fullerene derivatives, and is preferably selected from the group consisting of (6,6)-phenyl-C₆₁-butyric acid methyl ester (PCBM), (6,6)-phenyl-C₇₁-butyric acid methyl ester (C₇₀-PCBM), fullerene (C₆₀), (6,6)-thienyl-C₆₁-butyric acid methyl ester (ThCBM), carbon nanotubes and mixtures thereof.

To form the photoactive layer 6, examples of the solvent for simultaneously dissolving the electron donor material and the electron acceptor material include, but are not limited to, chloroform, chlorobenzene, dichlorobenzene, trichlorobenzene and mixtures thereof. Any solvent may be used as long as the electron donor material and the electron acceptor material can be dissolved therein.

The mixture of electron donor material and electron acceptor material prepared using the above materials is applied on the hole transfer layer 3, and the applied mixture is subjected to a nanoimprinting process, thus forming the patterns. The nanoimprinting process is performed by, before complete evaporation of the solvent of the mixture applied on the hole transfer layer 3, covering the mixture of the photoactive layer with a mold having a nanometer-sized pattern structure so that the mixture is sucked into the nano patterns of the mold using capillary force, and then evaporating the solvent, thus forming the structure opposite the structure of the mold on the surface of the photoactive layer. Alternatively, the nanoimprinting process may be performed by completely evaporating the solvent of the mixture applied on the hole transfer layer 3, applying predetermined heat to the lower surface of the substrate to thus make the mixture of the photoactive layer flexible, covering the mixture of the photoactive layer with the mold, applying pressure to the upper surface of the mold to thus press the mold, and removing the mold, thus forming the structure opposite the structure of the mold on the surface of the photoactive layer. As such, in the case where the electron donor 4 of the photoactive layer 6 is a conductive polymer, it is preferred that the nanoimprinting process be carried out at a temperature not lower than the glass transition temperature of the electron donor polymer.

In the present invention, the mold 9 may include protrusions having various shapes, such as a conical shape, a cylindrical shape, a cubic shape, a rectangular parallelepiped shape, a semi-circular shape, a hollow cylindrical shape, a hollow hexahedral shape, and a nanowire array, and examples of the material for the mold 9 include, but are not limited to, metal, metal oxide, ceramic, a semiconductor, and a thermosetting polymer. Any material may be used as long as it facilitates the production of a mold, is easily obtainable for purchase and is inexpensive.

The mold 9 having a nano pattern structure may be produced through various methods known in the art, including etching of a silicon wafer, anodization of metal such as aluminum, e-beam lithography, soft lithography such as nanoimprinting or capillary force lithography, or replication of a mold formed using the above methods.

In the present invention, the mold has the pattern structure having a pattern period of 1 μm or less and preferably 0.01˜1 μm. If the pattern period of the mold exceeds 1 μm, it is excessively larger than the size of the phase-separated electron acceptor, undesirably reducing electron transfer effects. In contrast, if the pattern period of the mold is less than 0.01 μm, it is shorter than the diffusion distance of excitons, and thus there are no effects for efficiency improvement, and also, the cathode electrode material does not infiltrate the photoactive layer.

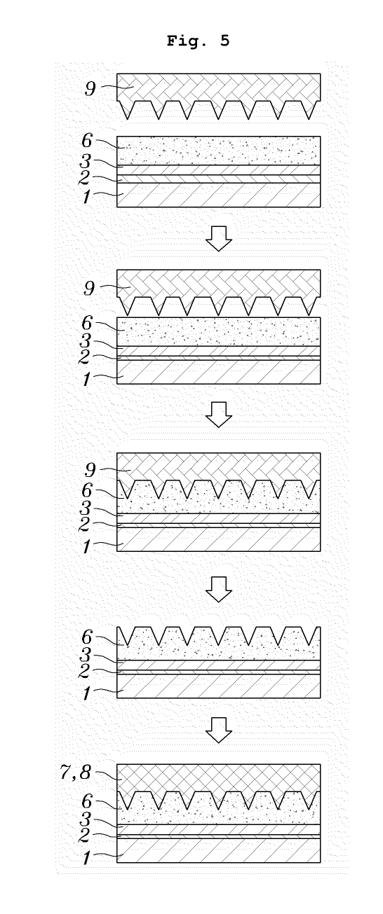

As shown in FIG. 5, the method of manufacturing the organic solar cell according to the present invention may further include, after forming the transparent electrode 2 on the substrate 1, applying a hole transfer material on the transparent electrode 2 thus forming a hole transfer layer 3. On the hole transfer layer 3 thus formed, the mixture of electron donor material and electron acceptor material dissolved in the solvent is applied, thus forming the photoactive layer 6, and then a nanoimprinting process is performed on the photoactive layer 6, thus patterning the upper surface of the photoactive layer 6. The cathode electrode material is directly applied on the patterned photoactive layer 6, thereby completing the organic solar cell.

Alternatively, the method of manufacturing the organic solar cell according to the present invention may further include, after formation of the patterns on the photoactive layer 6 using a nanoimprinting process, applying an electron transfer material on the patterned photoactive layer, thus forming an electron transfer layer 7. Then, the cathode electrode material is applied on the electron transfer layer 7, thereby completing the organic solar cell.

In the present invention, the hole transfer layer 3 is formed by applying the hole transfer material on the transparent electrode, and the material thereof may be selected from the group consisting of poly(3,4-ethylenedioxythiophene)-polystyrenesulfonate, polyaniline, copper phthalocyanine (CuPC), polythiophenylenevinylene, polyvinylcarbazole, poly-p-phenylenevinylene, poly(methylphenylsilane) and mixtures thereof.

In the present invention, the electron transfer layer 7 is formed by applying the electron transfer material such as lithium fluoride (LiF), calcium, lithium or titanium oxide on the photoactive layer which is patterned using the mold, and the cathode electrode material having low work function is applied thereon, thus forming the cathode electrode 8. The cathode electrode material may be selected from the group consisting of calcium, lithium, aluminum, an alloy of lithium fluoride and lithium, an alkali metal salt, a conductive polymer and mixtures thereof. The cathode electrode material may be applied on the photoactive layer 6 along with the electron transfer material.

After application of the cathode electrode on the photoactive layer 6 as mentioned above, thermal treatment at 50˜200° C. for 5˜60 min may be carried out. Such thermal treatment induces appropriate phase separation between the electron donor and the electron acceptor and also induces the orientation of the electron donor material. If the thermal treatment temperature is lower than 50° C., the mobility of the electron donor and electron acceptor is low, and thus thermal treatment effects become insignificant. In contrast, if the thermal treatment temperature is higher than 200° C., the electron donor material is deteriorated undesirably degrading the performance thereof.

According to another embodiment of the present invention, the organic solar cell is provided, which is manufactured using the above method and includes the photoactive layer having the bulk-heterojunction structure of the electron donor and the electron acceptor, in which the cathode electrode material infiltrates the photoactive layer.

In the organic solar cell according to the present invention, the metal electrode having high conductivity infiltrates the photoactive layer using a nanoimprinting process, so that the broken pathway for the transfer of electrons is made continuous, thus facilitating the transfer of electrons and reducing the number of electrons that disappear, consequently increasing the total photocurrent. In the present invention, electrons can be transferred to the cathode electrode layer made of a highly conductive metal, without the use of a hopping mechanism, resulting in an increased electron transfer rate and reduced electron transfer resistance. Also, when the nano patterns are formed on the photoactive layer using a nanoimprinting process, electron donor molecules can be aligned in a perpendicular direction, thus facilitating the transfer of holes to the transparent electrode, thereby reducing the electron transfer resistance and increasing power conversion efficiency.

A better understanding of the present invention may be obtained through the following examples, which are set forth to illustrate, but are not to be construed to limit the present invention.

### EXAMPLE 1

### Manufacturing of Organic Solar Cell Using Nanoimprinting After Drying of Photoactive Layer

1-1: Formation of Hole Transfer Layer

A glass substrate coated with ITO was washed with acetone and alcohol using a sonicator, and then subjected to plasma treatment using an oxygen plasma generator (PDC-32G, available from Harrick Plasma) in an oxygen atmosphere to thus remove organics from the surface thereof. A hydroxyl group was formed on the surface of ITO, so that the ITO surface was made hydrophilic. Subsequently, poly(3,4-ethylenedioxythiophene)-polystyrenesulfonate (available from Bayer) was applied on the hydrophilic surface of ITO through spin coating and then dried at 140° C., thus completely removing the solvent, thereby forming a hole transfer layer on the glass substrate.

1-2: Formation of Photoactive layer

30 mg of an electron donor material, for example, poly-3-hexylthiophene (P3HT) and 21 mg of an electron acceptor material, for example, PCBM were dissolved in 2 ml of dichlorobenzene, thus preparing a mixture, which was then applied through spin coating on the hole transfer layer formed in Example 1-1 in a nitrogen-filled glove box. The solvent of the applied mixture was completely evaporated, thus forming a photoactive layer.

1-3: Nanoimprinting

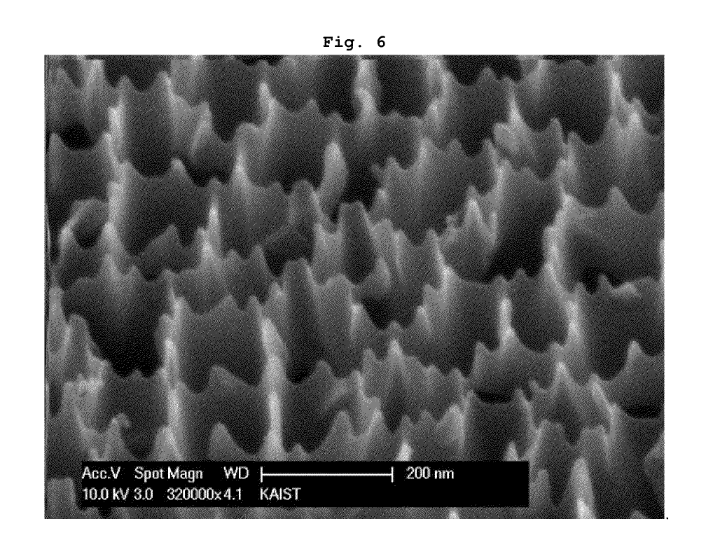

As a mold, a commercialized filter (Anodisc available from Whatman) made of anodized aluminum oxide (AAO) and having a pattern period of 0.2 μm was used. FIG. 6 shows the SEM image of the above mold at an inclined angle of 45°. The substrate having the photoactive layer formed in Example 1-2 was disposed on a plate heated to 150° C., the mold was placed on the photoactive layer, a flat metal plate was placed on the mold to apply predetermined pressure to the mold, pressure of 200 kPa was applied for 2 min, the mold was removed, and then drying was performed, thus forming patterns on the photoactive layer.

1-4: Formation of Electron Transfer Layer and Cathode Electrode

As an electron transfer layer, lithium fluoride (LiF) was vacuum deposited to a thickness of 1 nm on the photoactive layer patterned using nanoimprinting of Example 1-3, aluminum as a cathode electrode was vacuum deposited to a thickness of 150 nm, and then thermal treatment was performed 150° C. for 10 min, thus manufacturing an organic solar cell.

### EXAMPLE 2

### Manufacturing of Organic Solar Cell Using Nanoimprinting before Drying of Photoactive Layer

An organic solar cell was manufactured in the same manner as in Example 1, with the exception that, in Example 1-2, the mixture of the photoactive layer applied on the hole transfer layer was not dried, and the solvent of the mixture was dried in a state in which the mold was placed on the mixture of the photoactive layer directly after application of the mixture.

### Comparative Example 1

### Manufacturing of Organic Solar Cell having Bulk-Heterojunction Structure

An organic solar cell was manufactured in the same manner as in Example 1, with the exception that Example 1-3 was not performed.

### Comparative Example 2

### Manufacturing of Organic Solar Cell through Thermal Treatment before Application of Cathode Electrode

An organic solar cell was manufactured in the same manner as in Example 1, with the exception that, without nanoimprinting using the mold of Example 1-3, the substrate having the photoactive layer was disposed for 2 min on a plate heated to 150° C. and then dried, after which an electron transfer layer and a cathode electrode were sequentially formed on the photoactive layer.

### Experimental Example 1

### Comparison of Characteristics of Solar Cells

The current-voltage characteristics of the organic solar cells manufactured in Examples 1 and 2 and Comparative Examples 1 and 2 were compared using a solar simulator (66984 available from Newport). As the solar simulator, a 300 W xenon lamp (6258 available from Newport) and an AM1.5G filter (81088A available from Newport) were used, and the intensity of light was set to 100 mW/cm².

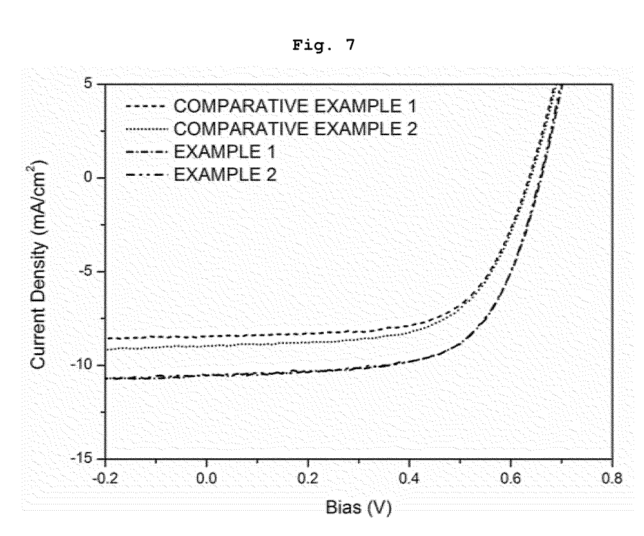

As is apparent from the results shown in Table 1 and FIG. 7, the organic solar cells of Examples 1 and 2 had very high short-circuit current compared to the organic solar cells of Comparative Examples 1 and 2. Further, in the evaluation of the effect of the thermal treatment for making the photoactive layer flexible during the nanoimprinting process of Example 1 on improvement of the short-circuit current, because the solar cell of Comparative Example 2 which was thermally treated at 150° C. for 2 min without the use of the mold had no power conversion efficiency effects compared to the organic solar cell of Comparative Example 1 which was not thermally treated, it could be confirmed that the improvement in the power conversion efficiency was not affected by the addition of the thermal treatment time.

TABLE 1

| | Ex. 1 | Ex. 2 | C. Ex. 1 | C. Ex. 2 |
|---|---|---|---|---|
| Power conversion Efficiency (%) | 4.41 | 4.43 | 3.42 | 3.53 |
| Short-Circuit Current Density | 10.5 | 10.5 | 8.45 | 8.97 |
| (mA/cm²) | | | | |
| Open Circuit Voltage (V) | 0.660 | 0.658 | 0.636 | 0.639 |
| Fill Factor | 0.635 | 0.640 | 0.637 | 0.616 |

As described hereinbefore, the present invention provides an organic solar cell and a method of manufacturing the same. According to the present invention, the method of manufacturing the organic solar cell enables a metal electrode having high conductivity to infiltrate a photoactive layer using nano patterns, thus increasing electrical conductivity and reducing loss of photocurrent occurring as a result of aggregation of an electron acceptor material. Further, in a nanoimprinting process, the molecular orientation of an electron donor is improved, resulting in a high-efficiency organic solar cell. Furthermore, the high-efficiency organic solar cell can be manufactured at low cost through a simple manufacturing process. Therefore, this method can be applied to the manufacturing of organic solar cells which use an environmentally friendly and recyclable energy source.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of manufacturing an organic solar cell, comprising:
(a) applying a transparent electrode material on a substrate, thus forming a transparent electrode;
(b) applying, on the transparent electrode, a mixture of an electron donor material and an electron acceptor material dissolved in a solvent, thus forming a photoactive layer, and then forming patterns on the photoactive layer using a nanoimprinting process; and
(c) applying a cathode electrode material on the patterned photoactive layer, thus forming a cathode electrode.

2. The method as set forth in claim 1, wherein the substrate is a glass substrate or a flexible polymer substrate.

3. The method as set forth in claim 1, wherein the transparent electrode material is selected from the group consisting of a transparent oxide, a conductive polymer, a carbon nanotube thin film, a graphene thin film, a graphene oxide thin film, a metal-combined carbon nanotube thin film and mixtures thereof.

4. The method as set forth in claim 1, wherein the electron donor material is selected from the group consisting of poly-3-hexylthiophene (P3HT), poly-3-octylthiophene (P30T), poly-p-phenylenevinylene (PPV), poly(9,9′-dioctylfluorene), poly(2-methoxy-5-(2-ethyl-hexyloxy)-1,4-phenylenevinylene (MEH-PPV), poly(2-methyl-5-(3′,7′-dimethyloctyloxy))-1,4-phenylenevinylene (MDMO-PPV) and mixtures thereof.

5. The method as set forth in claim 1, wherein the electron acceptor material is selected from the group consisting of (6,6)-phenyl-C₆₁-butyric acid methyl ester (PCBM), (6,6)-phenyl-C₇₁-butyric acid methyl ester (C₇₀-PCBM), fullerene (C₆₀), (6,6)-thienyl-C₆₁-butyric acid methyl ester (ThCBM), carbon nanotubes and mixtures thereof.

6. The method as set forth in claim 1, wherein the cathode electrode material is selected from the group consisting of calcium, lithium, aluminum, an alloy of lithium fluoride and lithium, an alkali metal salt, a conductive polymer and mixtures thereof.

7. The method as set forth in claim 1, wherein the solvent is selected from the group consisting of chloroform, chlorobenzene, dichlorobenzene, trichlorobenzene and mixtures thereof.

8. The method as set forth in claim 1, wherein the photoactive layer has a bulk-heterojunction structure of the electron donor material and the electron acceptor material.

9. The method as set forth in claim 1, wherein the nanoimprinting process is performed using a mold having a pattern structure in which a pattern period is 0.01˜1 μm.

10. The method as set forth in claim 9, wherein the mold is made of a material selected from the group consisting of a metal, a metal oxide, a ceramic, a semiconductor, a thermosetting polymer and mixtures thereof.

11. The method as set forth in claim 1, wherein the nanoimprinting process is performed by applying heat to a lower surface of the substrate to thus make the photoactive layer flexible, disposing a mold having a pattern structure on the photoactive layer, and applying pressure to an upper surface of the mold, thus forming the patterns on the photoactive layer.

12. The method as set forth in claim 1, wherein the nanoimprinting process is performed by, before evaporation of the solvent of the mixture of the photoactive layer, placing a mold having a pattern structure on the photoactive layer, thus forming the patterns on a surface of the photoactive layer using capillary force.

13. The method as set forth in claim 1, wherein the (c) further comprises performing thermal treatment, after forming the cathode electrode on the patterned photoactive layer.

14. The method as set forth in claim 1, wherein the (a) further comprises applying a hole transfer material on the transparent electrode thus forming a hole transfer layer, after forming the transparent electrode on the substrate.

15. The method as set forth in claim 14, wherein the hole transfer material is selected from the group consisting of poly(3,4-ethylenedioxythiophene)-polystyrenesulfonate, polyaniline, copper phthalocyanine (CuPC), polythiophenylenevinylene, polyvinylcarbazole, poly-p-phenylenevinylene, poly(methylphenylsilane) and mixtures thereof.

16. The method as set forth in claim 1, wherein the (b) further comprises applying an electron transfer material on the patterned photoactive layer thus forming an electron transfer layer, after forming the patterns on the photoactive layer using the nanoimprinting process.

17. The method as set forth in claim 16, wherein the electron transfer material is selected from the group consisting of lithium fluoride (LiF), calcium, lithium, titanium oxide and mixtures thereof.

18. An organic solar cell, manufactured using the method of claim 1 and comprising a photoactive layer having a bulk-heterojunction structure of an electron donor and an electron acceptor, in which a cathode electrode material infiltrates the photoactive layer.

19. A method of manufacturing an organic solar cell, comprising:
(a) applying indium tin oxide on a glass substrate, thus forming a transparent electrode;
(b) applying poly(3,4-ethylenedioxythiophene)-polystyrenesulfonate on the transparent electrode, thus forming a hole transfer layer;
(c) applying a mixture of poly-3-hexylthiophene and (6,6)-phenyl-C₆₁-butyric acid methyl ester dissolved in dichlorobenzene on the hole transfer layer, thus forming a photoactive layer, and then forming patterns on the photoactive layer using a nanoimprinting process;
(d) applying lithium fluoride on the patterned photoactive layer, thus forming an electron transfer layer; and
(e) applying aluminum on the electron transfer layer, thus forming a cathode electrode.

20. An organic solar cell, manufactured using the method of claim 19 and comprising a photoactive layer having a bulk-heterojunction structure of poly-3-hexylthiophene and (6,6)-phenyl-C₆₁-butyric acid methyl ester, in which a cathode electrode material infiltrates the photoactive layer.
